(19) United States
(12) Patent Application Publication
(10) Pub. No.: US 2009/0071526 A1
(43) Pub. Date: Mar. 19, 2009

(54) Sustained-heat source and thermogenerator system using the same

(75) Inventor: John J. Parker, Mount Laurel, NJ (US)

Correspondence Address: SEYFARTH SHAW, LLP, 815 CONNECTICUT AVENUE, N.W., SUITE 500, WASHINGTON, DC, 20006, US

(73) Assignee: ALLOY SURFACES COMPANY, INC., Chester Township, PA (US)

(21) Appl. No.: 11/898,919

(22) Filed: Sep. 17, 2007

(51) Int. Cl. H01L 35/30

(52) U.S. Cl. 136/205

(57) ABSTRACT

A thermogenerator system includes a sustained-heat source with a plurality of pyrophoric material elements each having a same geometric shape and in an encasement having openings, a thermal power generator for converting thermal energy from the sustained-heat source into electricity, and an electrical control system for regulating the electricity.

### BACKGROUND OF THE INVENTION

1. Field of the Invention

The embodiments of the invention relate to electricity generation, and more particularly, to a sustained-heat source and a thermogenerator system using the same. Although the embodiments of the invention are suitable for a wide scope of applications, they are particularly suitable for applications requiring portability and mobility.

2. Discussion of the Related Art

Portable energy systems are used every day, by commercial and military consumers alike, to power a wide variety of mobile electronic devices and micro-electro-mechanical (MEM) systems. Conventional portable energy systems include batteries and fuel cells, driven by electrochemical processes, and small-scale electrical generators, driven by thermo-mechanical processes. Less conventional portable energy systems include photovoltaic cells, driven by light; piezoelectric transducers, driven by vibration; and thermoelectric and thermionic generators, driven by heat.

Of the aforementioned portable energy systems, batteries are the most common, most available, and most affordable. However, recent advances in mobile electronics and MEM technology have created a growing need for innovative portable energy systems—ones having a voltage, current, and capacity that is much higher than that of batteries and other conventional portable energy systems.

Batteries present challenges related to energy density and hazardous material contents. Fuel cells, especially those fueled by hydrogen, have a much higher energy density than batteries, but present challenges related to production cost, fuel storage and transport, temperature and flow control, and service life. Small-scale electrical generators also have a much higher energy density than batteries, but present challenges related to fuel storage and transport, noise and exhaust reduction, and maintenance of moving parts. Photovoltaic cells and piezoelectric transducers are driven by light and vibration, but generally rely on the sun and wind to supply these driving forces. Therefore, photovoltaic cells and piezoelectric transducers present obvious challenges related to continuous and uninterrupted use.

Thermoelectric and thermionic generators are based on the Seebeck effect and Edison effect, respectively. Discovered by Thomas Seebeck in 1821, the Seebeck effect is “the development of a potential difference in a circuit where two different metals or semiconductors are joined and their junctions maintained at different temperatures. It is the basis of the thermocouple.” (CRC Handbook of Chemistry and Physics, 80th Edition, Page 2-56). Thermionic emission, also referred to as the Edison effect, was first discovered by Frederick Guthrie in 1873. Later rediscovered by Thomas Edison in 1880, the Edison effect is “the emission of electrons from a solid as a result of heat. The effect requires a high enough temperature to impart sufficient kinetic energy to the electrons to exceed the work function of the solid.” (CRC Handbook of Chemistry and Physics, 80th Edition, Page 2-57)

One example of the related art is U.S. Pat. No. 3,615,869, titled “Radioisotope Thermoelectric Generator.” This example of the related art employs radioisotopic materials, such as Strontium 90, Plutonium 238, Cerium 144, or Cesium 137, as sustained heat sources for thermoelectric generation of power. Radioactive decay of these radioisotopic materials generates a significant amount of heat, and also generates harmful nuclear radiation in the process. If not properly insulated and shielded, these radioisotopic materials present great safety and health risk to the human handler. Therefore, this example of the related art is best suited for unmanned and unmaintained applications in remote locations.

Another example of the related art is U.S. Pat. No. 4,106,279, titled “Wrist watch incorporating a thermoelectric generator.” This example of the related art employs the human wrist as a sustained heat source for thermoelectric generation of power. The normal skin temperature of the human wrist is only about 30° C., creating a very low temperature differential between it and ambient air. The amount of electrical power generated by such a low temperature differential may be enough to power a wrist watch, but is not enough to power most other mobile electronic devices and MEM systems. Therefore, this example of the related art is best suited for wearable mobile electronic devices and MEM systems requiring a very low amount of electrical power, and that can be worn with the hot junction of the thermoelectric generator in intimate contact with the wearer's skin.

Another example of the related art is U.S. Pat. No. 5,541,464, titled “Thermionic generator.” This example of the related art employs a flame as a sustained heat source for thermionic generation of power. The flame is generated by a gas burner system. Gas burner systems, like small-scale electrical generators, present challenges related to fuel storage and transport, and related to exhaust reduction. Therefore, this example of the related art is best suited for applications where fuels are in abundant and ready supply.

A final example of the related art is U.S. Pat. No. 6,987,329, titled “Fuel flexible thermoelectric micro-generator with micro-turbine.” This example of the related art employs a high temperature exhaust gas as a sustained heat source for thermoelectric (and thermo-mechanical) generation of power. The high temperature exhaust gas is generated by a hydrocarbon liquid fueled micro-combustion system. Micro-combustion systems present the same challenges as those presented by small-scale electrical generators. Therefore, this example of the related art is also best suited for applications where fuels are in abundant and ready supply.

The United States military currently relies heavily upon battery systems to power more than 500 different mobile electronic devices and MEM systems, spending more than 100 million dollars annually on the procurement of several different types of battery systems. Of the many different types of battery systems used by the United States military today, the BA-5590 Lithium/Sulfur Dioxide Primary Battery System is the most common, and is the only battery system of its type that has been proven successful in combat missions.

The BA-5590 and other similar battery systems present various human factor problems that have adverse effects on combat mission planning. On a typical five day combat mission, each soldier in a platoon carries several battery systems, including the BA-5590, with a total combined weight of about 35 pounds. However, soldiers who are required to carry this and other battery systems during combat missions complain that the battery systems are too heavy and bulky, and do not last long enough.

The BA-5590 and other similar battery systems also present various logistics problems that have adverse effects on combat mission readiness posture. The transportation and disposal of lithium battery systems is regulated by the United States Department of Transportation under regulation 49 CFR 100-181, in conjunction with exemption DOT-E-7052. The exemption permits only limited transportation of lithium battery systems, and imposes very extensive safety control measures, special provisions, and reporting requirements. As a result, the costs associated with proper shipment and carriage of lithium battery systems is relatively high. Even higher are the costs associated with proper disposal of lithium battery systems, which must be disposed of as hazardous waste.

In response various human factor and logistics problems related to the BA-5590 and other similar battery systems, the United States military is actively seeking alternative portable energy systems that are lighter, smaller, longer lasting, more powerful, and more environmentally benign.

### SUMMARY OF THE INVENTION

Accordingly, embodiments of the invention are directed to a sustained-heat source and a thermogenerator system using the same that substantially obviate one or more of the challenges due to limitations and disadvantages of the related art.

An object of embodiments of the invention is to provide a thermogenerator system having a higher voltage, current, and capacity than conventional battery systems of equal weight and volume.

Another object of embodiments of the invention is to provide a thermogenerator system having a lower weight and volume than conventional battery systems of equal voltage, current, and capacity.

Another object of embodiments of the invention is to provide a sustained-heat source that is not carcinogenic, mutagenic, or hazardous.

Additional features and advantages of embodiments of the invention will be set forth in the description that follows, and in part will be apparent from the description, or may be learned by practice of embodiments of the invention. The objectives and other advantages of the embodiments of the invention will be realized and attained by the structure particularly pointed out in the written description and claims hereof as well as the appended drawings.

To achieve these and other advantages and in accordance with the purpose of embodiments of the invention, as embodied and broadly described, the thermogenerator system includes a sustained-heat source with a plurality of pyrophoric material elements each having a same geometric shape and in an encasement having openings, a thermal power generator for converting thermal energy from the sustained-heat source into electricity, and an electrical control system for regulating the electricity.

In another aspect, a thermogenerator system includes a sustained-heat source with a pyrophoric material in an encasement having openings for a fractional open surface area of about 0.25 to about 0.005, a thermal power generator for converting thermal energy from the sustained-heat source into electricity, and an electrical control system for regulating the electricity.

In yet another aspect, a thermogenerator system includes a sustained-heat source having a pyrophoric material at a packing density in an encasement with a fractional open surface area, a thermal power generator that operates within a predetermined temperature range, and an electrical control system for regulating the electricity, wherein the packing density and fractional open surface are configured such that diffusion of an oxidizer is controlled in the pyrophoric material for providing a predetermined average duration temperature within a predetermined operating temperature range of the thermal power generator.

In another aspect, a sustained-heat source for a thermogenerator system includes a thermally conductive encasement having openings for a fractional open surface area of about 0.25 to about 0.005, and a plurality of pyrophoric material elements each having a same geometric shape sealed within the encasement in an inert atmosphere.

In yet another aspect, a sustained-heat source for a thermogenerator system includes a thermally conductive encasement having openings for a fractional open surface area of about 0.25 to about 0.005, and a pyrophoric material packed and sealed within the encasement in an inert atmosphere.

It is to be understood that both the foregoing general description and the following detailed description are exemplary and explanatory and are intended to provide further explanation of embodiments of the invention as claimed.

### BRIEF DESCRIPTION OF THE DRAWINGS

The accompanying drawings, which are included to provide a further understanding of embodiments of the invention and are incorporated in and constitute a part of this specification, illustrate embodiments of the invention and together with the description serve to explain the principles of embodiments of the invention. In the drawings:

FIG. 1 is a schematic diagram of a thermogenerator system of the embodiments of the invention including a sustained-heat source, a thermal power generator, and an electrical control system;

FIG. 2 is a schematic diagram for an embodiment of the invention having a sustained-heat source configured for using ambient atmosphere as an oxidizer;

FIG. 3 is a schematic diagram for an embodiment of the invention having a sustained-heat source configured for using an oxidizer delivery manifold;

FIG. 4 is a schematic diagram for an embodiment of the invention having a thermal power generator including thermoelectric modules;

FIG. 5 is a schematic diagram for an embodiment of the invention having a thermal power generator including thermionic modules; and

FIG. 6 is an illustration of an electrical control system shown in FIG. 1.

### DETAILED DESCRIPTION OF THE PREFERRED EMBODIMENTS

Reference will now be made in detail to the preferred embodiments of the invention, examples of which are illustrated in the accompanying drawings. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements.

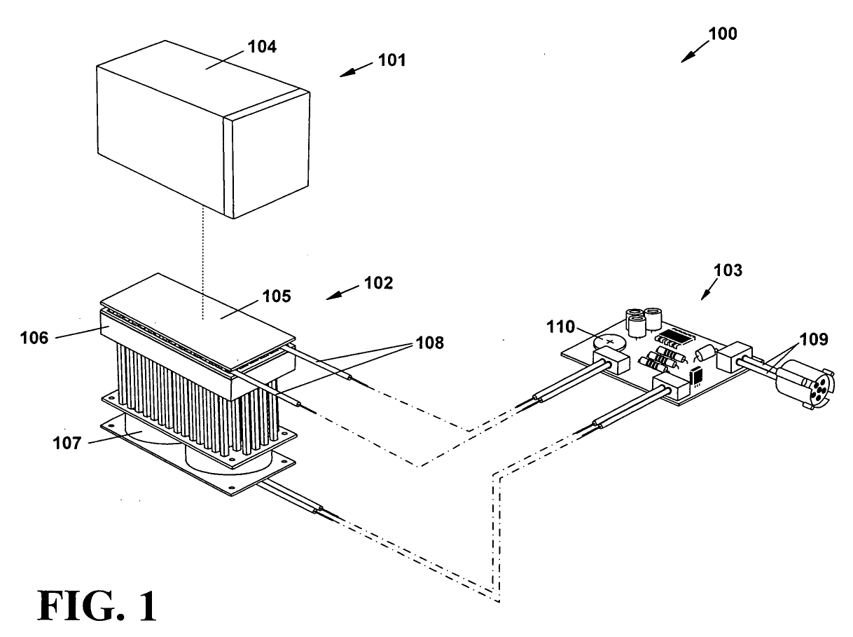

Embodiments of the invention provide a thermogenerator system for the conversion of thermal energy, generated by the enthalpy change that occurs when pyrophoric material is oxidized, into electrical energy. FIG. 1 is a schematic diagram of the thermogenerator system of embodiments of the invention. As shown in FIG. 1, the thermogenerator system 100 includes a sustained-heat source 101, a thermal power generator 102, and an electrical control system 103.

A sustained-heat source 101 maintains at least a predetermined temperature for several hours. The sustained-heat source 101 can be made by packing a pyrophoric material into a thermally conductive encasement 104. The walls of the thermally conductive encasement 104 must be sufficiently thick enough to retain the pyrophoric material and an inert atmosphere during transport and handling, but must be sufficiently thin enough to facilitate the efficient transfer of thermal energy from oxidizing pyrophoric material. Also, the material of construction for the thermally conductive encasement 104 must have a relatively high thermal conductivity. Cost effective materials with a high thermal conductivity include copper, aluminum, and brass. The inert atmosphere can be a vacuum or an atmosphere filled with one of or combination of non-oxygen containing gases, such as nitrogen or argon.

The sustained-heat source 101 is an expendable and replaceable element of the thermogenerator system 100. When a sustained-heat source 101 is used up or expended, the sustained-heat source 101 can be replaced with another sustained-heat source such that the thermogenerator system 100 can be used again to generate power. Accordingly, the thermal power generator 102 and the electrical control system 103 can be used repeatedly with different sustained-heat sources.

The thermal power generator 102 receives the thermal energy from the sustained-heat source 101 and converts the thermal energy with a thermal converter 105 into electrical energy. The thermal converter 105 can use either the Seebeck effect (reverse Peltier effect) or the Edison effect, which generate electricity based on thermal difference between a cold side and a hot side. Thermal energy rejected from the cold side of the thermal converter 105 can be transferred through a heat sink 106 by conductive heat transfer and then to ambient air and/or a liquid coolant by convective heat transfer. Fans 107 can be used to increase the heat dissipation capability of the heat sink 106. A thermal transfer agent (not shown) can be provided between such a heat sink 106 and the cold side of the thermal converter 105 to ensure an efficient thermal interface between the heat sink 106 and the cold side of the thermal converter 105.

Thermal to electric conversion efficiency is increased by increasing the thermal conductivity and surface area of the heat sink 106, by adding heat pipes or spreaders and/or by adding a continuous or intermittent cooling mechanism, such as fans 107. This, in effect, increases the electrical energy output of the thermal converter 105 by increasing its temperature differential. Possible cooling mechanisms include, but are not limited to, oscillating piezo fans, conventional rotary fans, ducting systems, liquid coolant exchange systems, and thermosiphons. Cooling mechanisms should have a sufficiently low power demand, such that the electrical energy output is not significantly decreased. Further, cooling mechanisms must have quiet operation to maintain covertness if the system is being used for military applications.

The electrical control system 103 receives the electrical energy from the thermal power generator 102 through electrical interconnections 108. The electrical control system 103 regulates the electrical energy for subsequent delivery at an appropriate voltage and current through the external electrical leads 109. Further, the electrical control system 103 can provide electrical power to the fans 107 of the thermal power generator 102.

The thermogenerator system 100 can be used to provide electrical power directly to electrical components or be used to recharge the batteries of electrical components. In addition or in the alternative, capacitor(s) and/or battery(ies) 110 can be incorporated into the electrical control system 103 of the thermogenerator system 100 to store excess electrical energy generated by the thermal power generator 102, such that the thermogenerator system 100 is capable of delivering power even after the oxidation reaction between the pyrophoric material and oxidizer has been completed. Capacitors are capable of storing and discharging electrical energy much faster than batteries, have much longer service life than that of batteries, and can be repeatedly recharged to full capacity throughout the entire service life. However, the storage capacity of a capacitor is dependent upon the surface area of the electrode plates in the capacitor. Batteries are capable of storing and discharging much greater amounts of electrical energy than capacitors.

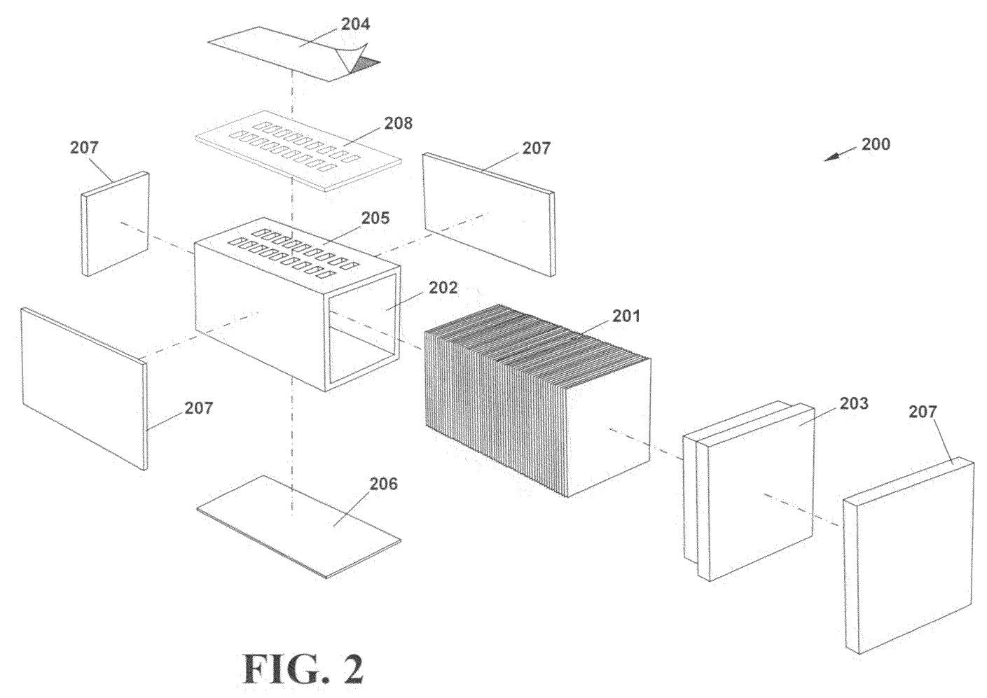

FIG. 2 is a schematic diagram for an embodiment of the invention having a sustained-heat source configured for using ambient atmosphere as an oxidizer. As shown in FIG. 2, the sustained-heat source 200 includes a pyrophoric material 201 in a thermally conductive encasement 202 sealed by an end cap 203 and by a removable hermetic seal 204 covering perforations 205 in a side of the thermally conductive encasement 202. The removable hermetic seal 204 can be manually removed by the user at the desired time of use such that the pyrophoric material 201 will react exothermically with oxygen gas present in the ambient atmosphere.

A thermally conductive material 206 is positioned on another side of the thermally conductive encasement 202, a different side of the thermally conductive encasement 202 than the side having the perforations 205, the side of the thermally conductive encasement 202 that will be facing the thermal power generator 102. The thermally conductive material 206 acts as thermal transfer agent to conduct heat from the thermally conductive encasement 202 to the thermal power generator 102. The thermally conductive material 206 should have a relatively high thermal conductivity, and sufficiently thin enough so as not to significantly impede heat flux. There are types of thermally conductive materials that are either dry to the touch, or have the ability to exist as a solid under normal conditions, but can undergo a phase change at elevated temperatures. Such materials are preferred over thermal greases, which are difficult and messy to work with. Examples of thermal phase change materials include salt hydrates, such as calcium chloride hexahydrate and sodium sulphate decahydrate, and may also include alkyl hydrocarbons, impregnated with a thermally conductive filler material such as boron nitride.

A thermally insulative material 207 can be affixed to sides of the thermally conductive encasement 202 that do not have the thermally conductive material 206. Further, the thermally insulative material 207 can be affixed to the external surface of the end cap 203. In addition, a perforated thermally insulative material 208 can be positioned on the side of the thermally conductive encasement 202 having the perforations 205 such that the perforated thermally conductive material 208 does not restrict flow of air into the thermally conductive encasement 202. Such placement of the thermally insulative material 207 prevents significant loss of heat to surroundings, thereby facilitating more efficient transfer of thermal energy to the thermal power generator 102. The thermally insulative material 207 should have a low thermal conductivity, and must be sufficiently thick enough to prevent significant loss of heat to the surroundings. Thermally insulative materials with a low thermal conductivity include polystyrene, polyvinyl chloride, polyurethane, polyimide, polyethylene, and fiberglass. However, to ensure an environmentally benign system, natural insulators, such as cork or cellulose fiber, can also be used.

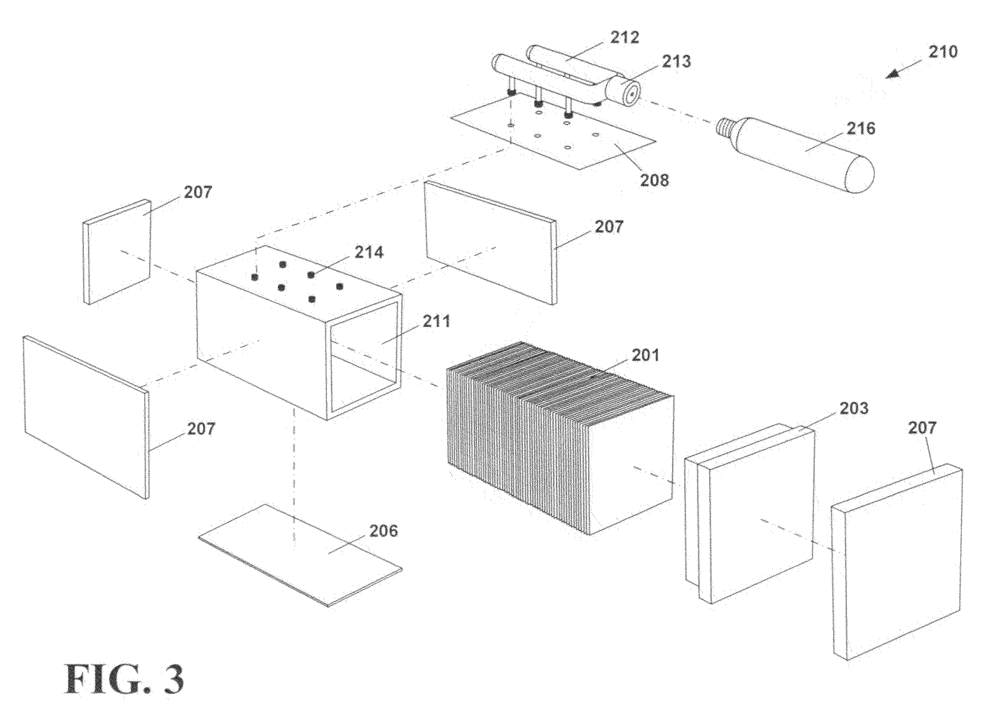

FIG. 3 is a schematic diagram for an embodiment of the invention having a sustained-heat source configured for using an oxidizer delivery system. As shown in FIG. 3, the sustained-heat source 210 includes pyrophoric material 201 in a thermally conductive encasement 211 sealed by an end cap 203 and by an oxidizer delivery manifold 212 with a one-way valve 213 that is connected to orifices 214 in a side of the thermally conductive encasement 211. A canister 216 of chemical oxidizer can be attached to the one-way valve 213 by the user at the desired time of use such that the pyrophoric material 201 will react exothermically with the chemical oxidizer from the canister 216.

A thermally conductive material 206 is positioned on another side of the thermally conductive encasement 212, a different side of the thermally conductive encasement 212 than the side having the orifices 214, the side of the thermally conductive encasement 212 that will be facing the thermal power generator 102. The thermally conductive material 206 acts as thermal transfer agent to conduct heat from the thermally conductive encasement 212 to the thermal power generator 102. Further, a thermally insulative material 207 can be affixed to sides of the thermally conductive encasement 212 that do not have the thermally conductive material 206. Furthermore, a thermally insulative material 207 can be affixed to the external surface of the end cap 203. In addition, a perforated thermally insulative material 208 can be positioned on the side of the thermally conductive encasement 212 having the orifices 214 such that the perforated thermally conductive material 208 surrounds portions of the manifold 212.

The pyrophoric material can be an activated pyrophoric metal, such as disclosed in U.S. Pat. No. 6,193,814. Such an activated pyrophoric metal is made by thermally diffusing (or reacting) at least one chemically inactive metal, such as aluminum or zinc, into (or with) at least one passivated pyrophoric metal, such as iron, nickel, manganese, boron, or cobalt. The chemically inactive metal is then selectively leached from the intermetallic compound by immersion into an aqueous caustic solution, such as sodium hydroxide, leaving behind an extremely porous, high surface area physical microstructure comprised of the now activated pyrophoric metal.

Although there is no preference with respect to a specific type of activated pyrophoric metal or metals, decisions can be made based on the relative cost-to-benefit ratio of each possible pyrophoric metal. The cost-to-benefit ratio is a function of the total cost to purchase and activate the pyrophoric metal, divided by the enthalpy of reaction (absolute value) between the pyrophoric metal or metals and chosen chemical oxidizer or oxidizers, the relative stoichiometric amount of each reagent present, and the fractional extent to which the oxidation reaction can reach completion. Lower cost-to-benefit ratios are preferred. Further, several different types of pyrophoric material, with different material properties, may be used, in combination, to achieve desired reaction kinetics and thermodynamic effects. Examples of such pyrophoric metals include finely divided metals, such as magnesium; alkali metals, such as sodium; metal hydrides, such as diborane; and metal carbonyls, such as dicobalt octacarbonyl.

In embodiments of the invention, mass-controlled oxidation reaction between the activated pyrophoric metal and the oxidizer, either ambient atmosphere as an oxidizer or a chemical oxidizer, can be diffusion-controlled by sufficiently limiting the migration of chemical oxidizer molecules to active sites on the surface and microsurface by compacting individual activated pyrophoric metal geometric elements, such as foil sheets, into an encasement with at least one opening. More specifically, the oxidation reaction between the activated pyrophoric metal and the chemical oxidizer is mitigated to exhibit a diffusion-controlled kinetic mechanism in lieu of a mass-controlled kinetic mechanism, such that the reaction rate constant is much greater than the mass transfer coefficient, and such that the peak temperature and duration can be tailored to the design limitations of a specific thermal converters without undermining the net thermal energy generation capacity of the oxidation reaction. For example, migration of the oxidizer molecules to active sites on the surface and microsurface of the individual activated pyrophoric metal foil elements can be controlled by compacting a plurality of the individual activated pyrophoric metal foil elements into a single activated pyrophoric metal stacked unit in an encasement with at least one opening.

Other geometries instead of stacks of foil can be used. For example, saddles, spheres, pellets and other three-dimensional shapes can be used instead of foil sheets. In other examples, a single foil sheet can be fan-folded into a stack or rolled into a coil. The geometric shape, surface and microsurface of the pyrophoric material elements determine packing density of the pyrophoric material. The geometric shape should be capable of maintaining packing density without settling. A slight compaction of the pyrophoric material elements having the geometric shape maintains consistency and prevents damage to the pyrophoric material elements due to movement of the pyrophoric material elements. Generally, embodiments of the present invention operate at packing densities between 150 and 300 foils per linear inch with individual foil elements measuring about 0.003 inch thick.

Packing densities that are too low will allow for a higher amount of direct contact between the oxidizer and activated pyrophoric metal surfaces (desirable), but will have a lower potential energy density (undesirable). Therefore, packing densities that are too low will result in a higher peak temperature oxidation reaction with a shorter duration, which will generate an unsatisfactory amount of thermal energy. However, packing densities that are too high will restrict the amount of direct contact between the oxidizer and activated pyrophoric metal surfaces (undesirable), but will have a higher potential energy density (desirable). Therefore, packing densities that are too high will result in a lower peak temperature oxidation reaction with a longer duration, which will also generate an unsatisfactory amount of thermal energy. Thus, a preferred packing density exists, and can be determined empirically for each activated pyrophoric metal composition and geometry considered. Chemical and physical properties of both the activated pyrophoric material and the oxidizer together, such as concentrations, pressure, diffusivity, and porosity are factors in determining a preferred packing density. Further, ambient conditions, such as temperature and pressure, and optimal operating parameters of the thermal power generator are also factors in determining a preferred packing density.

The temperature and duration of the oxidation can be further augmented by reducing the fractional open surface area. More specifically, migration of the oxidizer molecules to active sites on the surface and microsurface of the individual activated pyrophoric metal foil elements can be controlled by packing a single activated pyrophoric metal stacked unit into an encasement with fractional open surface area. The area of the perforation(s) or the orifice(s) of an encasement divided by the overall external surface area of the encasement is the fractional open surface area of an encasement. An encasement can have a single opening, a plurality of openings or a plurality of different-sized openings that are subsequently unsealed to allow oxidizer molecules into the encasement.

The average peak temperature of an oxidizing activated pyrophoric metal foil element is about 799° C. with an average duration above 400° C. of about 3.43 seconds (9.54E-04 hours). By compacting a plurality of the individual activated pyrophoric metal foil elements into a single pyrophoric metal foil stacked unit, migration of the oxidizer molecules to active sites on the surface and microsurface of the individual activated pyrophoric metal foil elements is limited. This is because the spaces (i.e., flow channels) between the individual activated pyrophoric metal foil elements in a single activated pyrophoric metal stacked unit are sufficiently small, such that the surface friction between the chemical oxidizer and the individual activated pyrophoric metal foil elements restricts flow and reduces the linear pressure of the oxidizer.

By packing the pyrophoric metal stacked unit into an encasement with a smaller fractional open surface area, migration of the oxidizer molecules to active sites on the surface and microsurface of the individual activated pyrophoric metal foil elements is further controlled. This is because flow of the oxidizer incident and parallel to the spaces (i.e., flow channels) between the individual activated pyrophoric metal foil elements in a single activated pyrophoric metal stacked unit is sufficiently low, such that diffusion of the oxidizer is controlled for providing a predetermined average duration temperature that is at least within the preferred operating temperature range of the thermal converter. Generally, embodiments of the present invention operate with a fractional open surface area of about 0.25 to about 0.005. Accordingly, both fractional open surface area and packing density can be configured such that diffusion of an oxidizer is controlled in the pyrophoric material elements to provide a predetermined average duration temperature within the predetermined operating temperature range of the thermal power generator. Typically, the predetermined operating temperature range of the thermal power generator is a temperature range in which thermogenerator operates efficiently. For example, the predetermined operating temperature range can be plus and minus twenty-five percent of the optimal operating temperature of the thermal power generator.

After the activated pyrophoric metal is packed into the thermally conductive encasement, the thermally conductive encasement is hermetically sealed to have an inert atmosphere. This prevents the possibility of any premature passivation of the activated pyrophoric metal. The hermetic seal, in one embodiment of the sustained-heat source, is one that can be manually removed by the user at the desired time of use. Thus, for the embodiment having a removable hermetic seal 204, as shown in FIG. 2, the oxidizer is oxygen gas present in the ambient atmosphere such that the oxidation of the pyrophoric material is an open system reaction.

In contrast, a canister 216 containing a chemical oxidizer is attached to the one-way valve 213 in the embodiment having on oxidizer delivery manifold 212, as shown in FIG. 3, to provide the oxidation of the pyrophoric material is a closed system reaction. Thus, the canister 216 should be transported and provided for use with the embodiment having on oxidizer delivery manifold 212 when thermal generation is desired. A closed system is not subjected to any contaminants present in the ambient atmosphere that may adversely affect the oxidation reaction.

In the alternative, the one-way valve 213 can be removed from the oxidizer delivery manifold 212 so that the oxidizer is oxygen gas present in the ambient atmosphere if a canister 216 of the chemical oxidizer is unavailable. The oxidation of the pyrophoric material, which was configured for use with a chemical oxidizer from the canister 216, may not deliver as much of a heat differential to the thermal converts as when the pyrophoric material is oxidized with the chemical oxidizer from the canister 216. Thus, the pyrophoric material of the embodiment having on oxidizer delivery manifold 212 can be designed to alternatively operate as an open system reaction.

When the hermetic seal is removed or when a chemical oxidizer is introduced into the thermally conductive encasement thermal energy is generated by the enthalpy change that occurs when the activated pyrophoric metal is oxidized. The enthalpy change that occurs is dependant upon the activated pyrophoric metal or metals that are being oxidized, and also the chemical oxidizer or oxidizers that are being reduced. The enthalpy change that occurs is also dependant upon the fractional extent to which the oxidation reaction can reach completion, governed by packing density and the fractional open surface area of an encasement. The preferred oxidizer is oxygen, since oxygen yields no reaction products other than a solid metal oxide. The preferred source for obtaining oxygen is the ambient atmosphere, since an open reaction system eliminates the necessity for in-situ storage and transportation of an oxidizer in a canister. However, if the ambient atmosphere is polluted with dust or smoke, or if oxygen gas is not present in the ambient atmosphere (such as in underwater applications), a closed reaction system is preferred. Alternative chemical oxidizers may be used in lieu of oxygen; however, the chemical oxidizer, and any reaction product, is preferably user-safe and environmentally benign.

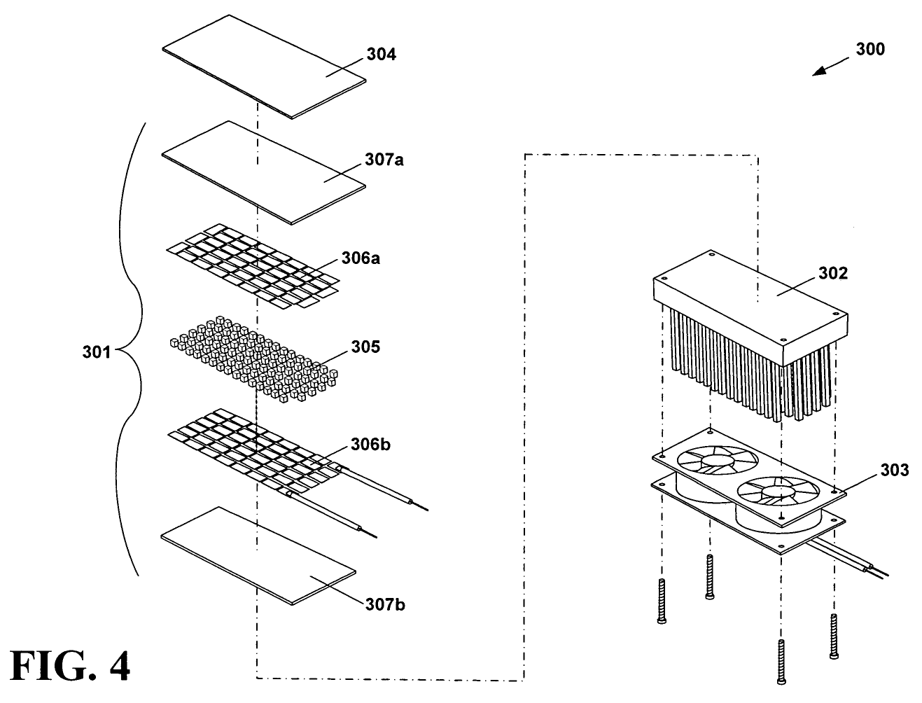

FIG. 4 is a schematic diagram for an embodiment of the invention having a thermal power generator including thermoelectric modules. As shown in FIG. 4, the thermal power generator 300 includes thermoelectric module 301, and ancillary components for the efficient transfer of thermal energy, such as heat sink 302 for cooling the cold side of the thermoelectric module 301, a cooling fan 303 for the heat sink 302 and a thermally conductive material 304 used as a thermal transfer agent to the hot side of the thermoelectric module 301. Thermoelectric module 301 includes n-type and p-type thermoelements 305 between electrically conductive interconnects and wire leads 306a and 306b, which are between electrically insulative substrates 307a and 307b.

For thermal power generators of the thermoelectric variety, the following physical properties of (a) length, (b) width, (c) thickness, (d) mass, (c) maximum compression stress, and (d) number of n-type and p-type thermoelement active couples should be appropriate to the application. The following thermal properties of (a) maximum continuous operating temperature, (b) maximum intermittent operating temperature, (c) nominal hot junction temperature, (d) nominal cold junction temperature, (e) thermal conductivity as a function of the hot and cold junction temperatures, and (f) heat flux as a function of the hot and cold junction temperatures for each selected thermoelectric module(s) should be appropriate to the application. Further, the following electrical properties of (a) voltage as a function of the hot and cold junction temperatures, (b) current as a function of the hot and cold junction temperatures, (c) power as a function of the hot and cold junction temperatures, and (d) the electrical resistivity as a function of the hot and cold junction temperatures of each selected thermoelectric module(s) should also be appropriate to the application.

The melting point of the solder material used for thermoelectric module(s) construction can be a limiting factor to the maximum continuous and intermittent temperature rating of the thermoelectric module(s). When the thermoelectric module(s) are exposed to temperatures above the maximum rating, the solder joints will begin to melt, negatively affecting the performance of the thermoelectric module(s), and also potentially causing irreversible damage to the thermoelectric module(s). Thus, a solder material with a relatively high melting point, such as lead-antimony or tin-antimony should be used. However, the solder material should not chemically or physically interact with the thermoelectric material.

Thermoelectric conversion efficiency of a thermoelectric module(s) is expressed as the electrical energy output divided by the thermal energy input, and is variable with respect to the temperature difference between hot and cold junctions and with respect to the thermoelectric material being used. Thermoelectric conversion efficiency can be increased by using materials with a higher thermoelectric figure-of-merit, such as bismuth-telluride and lead telluride, and/or by increasing the number of n-type and p-type thermoelement active couples per unit area (wired electrically in series and thermally in parallel), or by decreasing thermoelement thickness. This, in effect, increases the electrical energy output of the thermoelectric module(s) by increasing its heat flux and current carrying capacity.

As the temperature difference between the hot and cold junctions of a thermoelectric module(s) increases, so does the thermoelectric conversion efficiency. However, at some nominal temperature difference, the thermoelectric conversion efficiency will reach a maximum value, and will decrease thereafter as the temperature difference continues to increase above this nominal temperature difference. Under these extreme conditions, multistage (cascaded) thermoelectric module(s) generally are required, since they are capable of pumping more thermal energy per unit time—a system capability which becomes necessary at reduced thermoelectric conversion efficiency. The use of multistage (cascaded) thermoelectric module(s) can significantly add to the cost of the solid-state thermogenerator component of the system, and can significantly subtract from the gravimetric and volumetric energy density of the system as a whole. Thus, when working with extreme hot junction temperatures, thermal power generators of the thermionic variety are preferred, since they are capable of achieving higher conversion efficiencies.

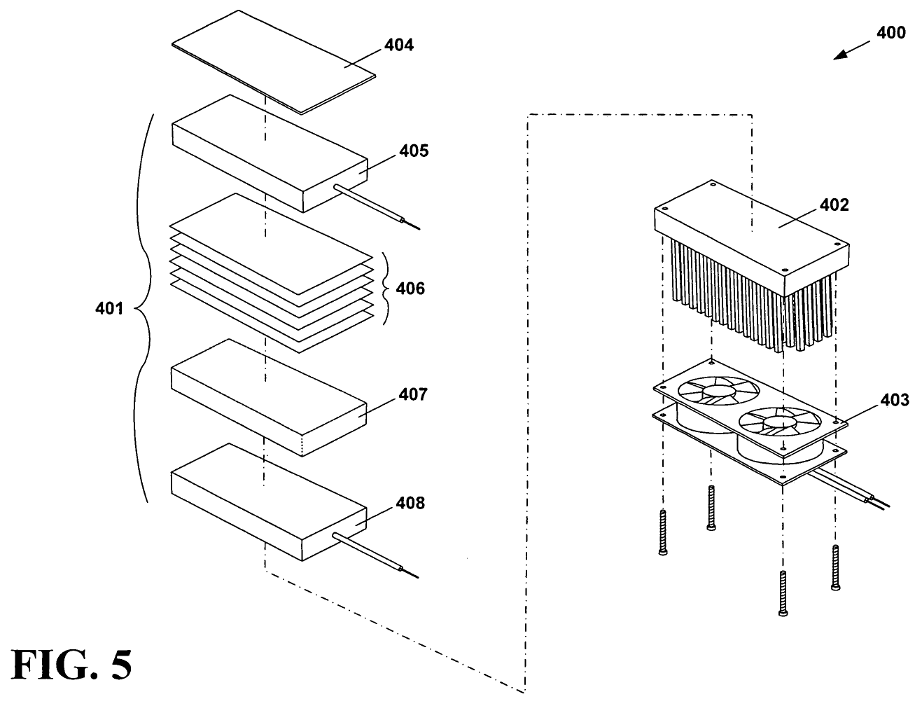

As shown in FIG. 5, the thermal power generator 400 includes thermionic module 401, and ancillary components for the efficient transfer of thermal energy, such as heat sink 402 for cooling the cold side of the thermionic module 401, a cooling fan 403 for the heat sink 402 and a thermally conductive material 404 used as a thermal transfer agent to the hot side of the thermionic module 401. Thermionic module 401 includes emitter material 405, barrier material 406, vacuum gap 407 (or semiconductor gap material, not shown), and collector material 408.

For thermal power generators of the thermionic variety, the following physical properties of (a) overall length, (b) overall width, (c) overall mass, (d) the thickness of the emitter material, (e) the thickness of the barrier material, (f) the thickness of the vacuum gap, and (g) the thickness of the collector material should be appropriate for the application. The following thermal properties of (a) minimum hot junction temperature required to impart the necessary amount of kinetic energy for electrons to exceed the work function of the solid junction emitter material, (b) thermal conductivity of the barrier material, (d) thermal conductivity of the collector material, and (e) heat flux arriving at the collector material for each selected thermionic module(s) should be appropriate for the application. The following quantum and electrical properties of (a) the work function of the emitter material, (b) emitted current density across the vacuum gap, (c) permittivity of the barrier material relative to that of the vacuum gap, (d) voltage as a function of the hot and cold junction temperatures, (e) current as a function of the hot and cold junction temperatures, and (f) power as a function of the hot and cold junction temperatures for each selected thermionic module(s) should be appropriate for the application.

Thermionic conversion efficiency can be increased by using a multi-barrier thermionic module, having two or more layers of barrier materials stacked thermally in series to the necessary barrier height. Multiple layers of thin barrier materials create a stepped effect in overall barrier height, in that each single band represents an approximately equal potential difference between the Fermi energy of the emitter material and that of the conduction band edge, where the charge carrier density is the greatest. As a result, several layered charge carrier regions exist across the totality of the multi-barrier stack, and each single band is sufficiently thin enough to not impede the flow of electrons. The net effect is a negligible temperature difference between the emitter material and conduction band edge of the last single band in the multi-barrier stack.

Thermionic conversion efficiency can also be increased by using thermionic module(s) with a vacuum gap sufficiently narrow enough to promote the thermotunneling of electrons from the barrier material to the collector material. Thermotunneling is a quantum mechanical electron transport phenomenon that occurs when energized electrons, with a kinetic energy exceeding the work function of the emitter material, travel between two electrodes (i.e., the barrier material and the collector material) across a vacuum gap of a thickness less than or equal to the mean free path of the energized electrons. The net effect is a negligible collision frequency between traverse electrons across the narrow vacuum gap, which, in turn, significantly reduces energy losses due to thermal conduction. Further, thermotunnel-type thermionic module(s) are capable of efficient operation at lower hot junction temperatures, relative to conventional-type thermionic module(s).

In the case of thermoelectric conversion, a thermally-induced electromotive force, or thermoemf, is generated by, and is proportional to the temperature differential between the hot and cold junctions of the thermoelectric module. In the case of thermionic conversion, thermoemf is generated by, and is proportional to not only the temperature differential between the hot and cold junctions of the thermionic module, but also the hot junction temperature of the thermionic module. This is because the Edison effect requires extreme hot junction temperature to impart the necessary amount of kinetic energy for electrons to exceed the work function of the solid junction material. In both cases, the resulting electrical current delivers continuous power to an external load, specifically the user's electronic device. A thermionic module generally delivers this continuous power with a higher conversion efficiency relative to the thermoelectric module, but require extreme hot junction temperatures to operate. A thermoelectric module generally delivers this continuous power with a lower conversion efficiency relative to a thermionic module, but can operate at hot junction temperatures much lower than that of the thermionic module.

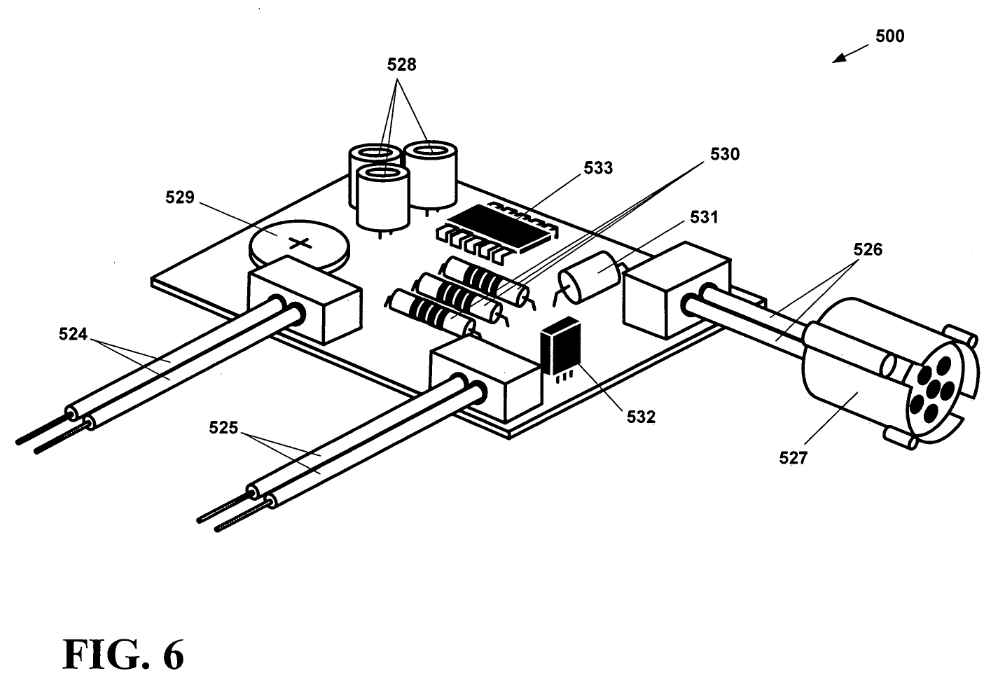

FIG. 6 is an illustration of the electrical control system shown in FIG. 1. Referring to FIG. 6, The integrated electrical circuit 500 includes input electrical leads 524 from the thermoelectric or thermionic module, cooling electrical leads 525 to the intermittent or continuous cooling mechanism, output electrical leads 526 can be connected to an external load through an interface terminal connector 527 (or wired directly to the external electrical load), and ancillary components for the efficient storage and regulated discharge of electrical energy. Ancillary components may or may not include one or more capacitors 528 or batteries 529, for the efficient storage and discharge of electrical energy; resistors 530, voltage regulators 531, and/or current regulators 532, for the regulated discharge of electrical energy; and other devices 533 (e.g., microchips, as shown in FIG. 6), to perform various digital and analog functions.

Capacitors or batteries can be used to efficiently store excess electrical energy generated by the thermogenerator system, such that the system is capable of delivering power even after the oxidation reaction has reached completion. Capacitors are capable of storing and discharging electrical energy much faster than batteries, have a much longer service life than that of batteries, and can be repeatedly recharged to full capacity throughout the entire service life. However, the storage capacity of a capacitor is limited by the surface area of its electrode plates. Batteries are capable of storing and discharging much greater amounts of electrical energy than capacitors. However, the storage capacity of a battery significantly decreases with each subsequent recharge. Capacitors are preferred over batteries, given the objects of the preferred embodiments of the present invention (i.e., to provide an alternative to batteries), and given the challenges presented by batteries (as a related art form).

A voltage regulator may be used to regulate the discharge of electrical energy generated by the thermogenerator system, such that it can be discharged at one or more predetermined voltage. The simplest type of voltage regulator is a variable resistor; however, variable resistors experience resistive losses, and quickly fail as a result of corrosion or wearing of the sliding contact. Therefore, more complex voltage regulators, such as linear and switching voltage regulators, are preferred. In general, switching regulators are preferred over linear regulators for applications requiring low weight, low volume, and high efficiency.

A variable resistor may also be used as a current regulator, such that the electrical energy generated by the thermogenerator system can be discharged at one or more predetermined current. However, variable resistors generally are unable to respond quickly enough to compensate for current fluctuations. Therefore, a current regulator constructed from a transistor, voltage reference diode (e.g., Zener diode), and resistors is preferred over a variable resistor.

### Example 1

The following example is intended to demonstrate (quantitatively) the effect of packing density on temperature and duration.

Pluralities of individual elements were packed into three alloy 6061-T6 aluminum encasements. The individual elements measured about 0.8 inch long, 1.75 inches wide, and 0.003 inch thick. The aluminum encasements measured about 8 inches long, 2 inches wide, and 1 inch thick (external dimensions), with a wall thickness of about 0.06 inch.

The first of the three aluminum encasements was packed to a combined total weight of about 675 grams, the second to a combined total weight of about 500 grams, and the third to a combined total weight of about 350 grams. The combined total weights represent the subtotal weights of the pluralities of individual elements plus the subtotal weight of the aluminum encasement. The combined total length, which is the subtotal length of the pluralities of individual elements plus the subtotal length of the end caps, is equal to the total length of the aluminum encasement.

To determine the subtotal weights of the pluralities of individual elements, the subtotal weight of the aluminum encasement (169 grams) was subtracted from the combined total weights provided above; to determine the subtotal length of the pluralities of individual elements, the subtotal length of the end caps (1.5 inch) was subtracted from the total length of the aluminum encasement (8 inches). Accordingly, the first of the three aluminum encasements was packed to a density of about 77.8 grams per inch, the second to a density of about 50.9 grams per inch, and the third to a density of about 27.8 grams per inch.

The three aluminum encasements were perforated to about 12% open surface area. The perforation was a single rounded rectangle measuring about 6.5 inches long and 1.0 inch wide, and having 0.5 inch corner radii.

As the pluralities of individual elements reacted with oxygen gas present in ambient air, thermocouple probes measured the surface temperature of the opposite external surface of the aluminum encasement as a function of time. TABLE 1 provides a summary approximation of key data points.

TABLE 1

| | Encasement 1 | | Encasement 2 | | Encasement 3 | |
|---|---|---|---|---|---|---|
| | ρ = 77.8 | | ρ = 50.9 | | ρ = 27.8 | |
| | g · in⁻¹ | | g · in⁻¹ | | g · in⁻¹ | |
| Peak temperature | 112° | C. | 108° | C. | 90° | C. |
| Reaction duration | 9-10 | hrs | 5-6 | hrs | 2-3 | hrs |
| Time to reach peak | 1.8 | hrs | 1.5 | hrs | 1.7 | hrs |
| temperature | | | | | | |
| Time at 80-90° C. | 1.7 | hrs | 0.4 | hrs | 2.5 | hrs |
| Time at 90-100° C. | 4.5 | hrs | 1.0 | hrs | 0.0 | hrs |
| Time above 100° C. | 3.3 | hrs | 4.1 | hrs | 0.0 | hrs |
| Median temperature | 99° | C. | 102° | C. | 89° | C. |
| during reaction | | | | | | |

### Example 2

The following example is intended to demonstrate (quantitatively) the effect of encasement perforation on temperature and duration.

Pluralities of individual elements were packed into two alloy 6061-T6 aluminum encasements, to a density of about 77.8 grams per inch. The individual elements measured about 0.8 inch long, 1.75 inches wide, and 0.003 inch thick. The aluminum encasements measured about 8 inches long, 2 inches wide, and 1 inch thick (external dimensions), with a wall thickness of about 0.06 inch.

The first of the two aluminum encasements was perforated to about 6% open surface area. The perforation was a single rounded rectangle measuring about 6.5 inches long and 0.50 inch wide, and having 0.25 inch corner radii. The second of the two aluminum encasements was perforated to about 12% open surface area. The perforation was a single rounded rectangle measuring about 6.5 inches long and 1.0 inch wide, and having 0.5 inch corner radii.

As the pluralities of individual elements reacted with oxygen gas present in ambient air, thermocouple probes measured the surface temperature of the opposite external surface of the aluminum encasement as a function of time. TABLE 2 provides a summary approximation of key data points.

TABLE 2

| | Encasement 1 | | Encasement 2 | |
|---|---|---|---|---|
| | 6% open surface area | | 12% open surface area | |
| Peak temperature | 87° | C. | 112° | C. |
| Reaction duration | 14-15 | hrs | 9-10 | hrs |
| Time to reach peak | 2.8 | hrs | 1.8 | hrs |
| temperature | | | | |
| Time at 80-90° C. | 4.9 | hrs | 1.7 | hrs |
| Time at 90-100° C. | 0.0 | hrs | 4.5 | hrs |
| Time above 100° C. | 0.0 | hrs | 3.3 | hrs |
| Median temperature | 75° | C. | 99° | C. |
| during reaction | | | | |

### Example 3

The following example is intended to demonstrate (quantitatively) the effect of encasement size and geometry on temperature and duration.

Pluralities of individual elements were packed into two alloy 6061-T6 aluminum encasements, to a density that is equal on the basis of number of individual elements per inch. The corresponding packing densities, on the basis of mass per unit length, are 77.8 grams per inch for the first of the two aluminum encasements, and 35.6 grams per inch for the second of the two aluminum encasements.

The first of the two aluminum encasements measured about 8 inches long, 2 inches wide, and 1 inch thick (external dimensions), with a wall thickness of about 0.06 inch. The individual elements within this aluminum encasement measured about 0.8 inch long, 1.75 inches wide, and 0.003 inch thick.

The second of the two aluminum encasements measured about 8 inches long, 1 inch wide and 1 inch thick (external dimensions), with a wall thickness of about 0.06 inch. The individual elements within this aluminum encasement measured about 0.8 inch long and wide, and about 0.003 inch thick.

The two aluminum encasements were both perforated to about 12% open surface area. The perforation of the first of the two aluminum encasements was a single rounded rectangle measuring about 6.5 inches long and 1.0 inch wide, and having 0.5 inch corner radii. The perforation of the second of the two aluminum encasements was a single rounded rectangle measuring about 6.0 inches long and 0.75 inch wide, and having 0.375 inch corner radii.

As the pluralities of individual elements reacted with oxygen gas present in ambient air, thermocouple probes measured the surface temperature of the opposite external surface of the aluminum encasement as a function of time. TABLE 3 provides a summary approximation of key data points.

TABLE 3

| | |
|---|---|
| Encasement 1 | Encasement 2 |
| 8 × 2 × 1 inches | 8 × 1 × 1 inches |

| | | | | |
|---|---|---|---|---|
| Peak temperature | 112° | C. | 112° | C. |
| Reaction duration | 9-10 | hrs | 7-8 | hrs |
| Time to reach peak | 1.8 | hrs | 1.3 | hrs |
| temperature | | | | |
| Time at 80-90° C. | 1.7 | hrs | 2.2 | hrs |
| Time at 90-100° C. | 4.5 | hrs | 1.7 | hrs |
| Time above 100° C. | 3.3 | hrs | 2.1 | hrs |
| Median temperature | 99° | C. | 90° | C. |
| during reaction | | | | |

It will be apparent to those skilled in the art that various modifications and variations can be made in the thermogenerator system of embodiments of the invention without departing from the spirit or scope of the invention. Thus, it is intended that embodiments of the invention cover the modifications and variations of this invention provided they come within the scope of the appended claims and their equivalents.

What is claimed is:

1. A thermogenerator system comprising:
a sustained-heat source with a plurality of pyrophoric material elements each having a same geometric shape and in an encasement having openings;
a thermal power generator for converting thermal energy from the sustained-heat source into electricity; and
an electrical control system for regulating the electricity.

2. The thermogenerator system of claim 1, wherein the electrical control system can store excess electrical energy generated by the thermal power generator.

3. The thermogenerator system of claim 1, wherein the thermal power generator includes a heat sink cooled by a fan that receives power from the electrical control system.

4. The thermogenerator system of claim 1, wherein the sustained-heat source is expendable and replaceable such that the thermal power generator for converting thermal energy and the electrical control system can be used with different sustained-heat sources.

5. The thermogenerator system of claim 1, wherein the openings are covered by a removable hermetic seal.

6. The thermogenerator system of claim 1, wherein the openings receive an oxidizer delivery manifold.

7. The thermogenerator system of claim 1, wherein the thermal power generator includes at least one of thermoelectric and thermionic modules.

8. The thermogenerator system of claim 1, wherein the thermal power generator includes thermotunnel-type thermionic modules.

9. The thermogenerator system of claim 1, wherein the geometric shape is a foil sheet and the foil sheets of pyrophoric material elements are stacked.

10. The thermogenerator system of claim 1, wherein the pyrophoric material includes at least one activated pyrophoric metal.

11. A thermogenerator system comprising:
a sustained-heat source with a pyrophoric material in an encasement having openings for a fractional open surface area of about 0.25 to about 0.005;
a thermal power generator for converting thermal energy from the sustained-heat source into electricity; and
an electrical control system for regulating the electricity.

12. The thermogenerator system of claim 11, wherein the electrical control system of the thermogenerator system can store excess electrical energy generated by the thermal power generator.

13. The thermogenerator system of claim 11, wherein the thermal power generator includes a heat sink cooled by a fan that receives power from the electrical control system.

14. The thermogenerator system of claim 11, wherein the sustained-heat source is expendable and replaceable such that the thermal power generator for converting thermal energy and the electrical control system can be used with different sustained-heat sources.

15. The thermogenerator system of claim 11, wherein the openings are covered by a removable hermetic seal.

16. The thermogenerator system of claim 11, wherein the openings receive an oxidizer delivery manifold.

17. The thermogenerator system of claim 11, wherein the thermal power generator includes one of thermoelectric and thermionic modules.

18. The thermogenerator system of claim 11, wherein the thermal power generator includes thermotunnel-type thermionic modules.

19. The thermogenerator system of claim 11, wherein the pyrophoric material element is stacked.

20. The thermogenerator system of claim 11, wherein the pyrophoric material includes at least one activated pyrophoric metal.

21. A thermogenerator system comprising:
a sustained-heat source having a pyrophoric material at a packing density in an encasement with a fractional open surface area;
a thermal power generator that operates within a predetermined temperature range; and
an electrical control system for regulating the electricity,
wherein the packing density and fractional open surface area are configured such that diffusion of an oxidizer is controlled in the pyrophoric material for providing a predetermined average duration temperature within the predetermined operating temperature range of the thermal power generator.

22. The thermogenerator system of claim 21, wherein the electrical control system of the thermogenerator system can store excess electrical energy generated by the thermal power generator.

23. The thermogenerator system of claim 21, wherein the thermal power generator includes a heat sink cooled by a fan that receives power from the electrical control system.

24. The thermogenerator system of claim 21, wherein the sustained-heat source is expendable and replaceable such that the thermal power generator for converting thermal energy and the electrical control system can be used with different sustained-heat sources.

25. The thermogenerator system of claim 21, wherein the encasement includes openings covered by a removable hermetic seal.

26. The thermogenerator system of claim 21, wherein the encasement includes openings receiving an oxidizer delivery manifold.

27. The thermogenerator system of claim 21, wherein the thermal power generator includes one of thermoelectric and thermionic modules.

28. The thermogenerator system of claim 21, wherein the thermal power generator includes thermotunnel-type thermionic modules.

29. The thermogenerator system of claim 21, wherein the pyrophoric material is stacked.

30. The thermogenerator system of claim 21, wherein the pyrophoric material includes at least one activated pyrophoric metal.

31. A sustained-heat source for a thermogenerator system comprising:
a thermally conductive encasement having openings for a fractional open surface area of about 0.25 to about 0.005; and
a plurality of pyrophoric material elements each having a same geometric shape sealed within the encasement in an inert atmosphere.

32. The sustained-heat source of claim 31, wherein a thermally conductive material is positioned on a side of the thermally conductive encasement for transferring heat to a thermal power generator.

33. The sustained-heat source of claim 32, wherein a thermally insulative material is positioned on other sides of the thermally conductive encasement.

34. The sustained-heat source of claim 31, further comprising a removable hermetic seal covering the openings.

35. The sustained-heat source of claim 31, further comprising an oxidizer delivery manifold in the openings.

36. The sustained-heat source of claim 31, wherein the pyrophoric material elements are stacked.

37. The sustained-heat source of claim 31, wherein the pyrophoric material includes at least one activated pyrophoric metal.

38. A sustained-heat source for a thermogenerator system comprising:
a thermally conductive encasement having openings for a fractional open surface area of about 0.25 to about 0.005; and
a pyrophoric material packed and sealed within the encasement in an inert atmosphere.

39. The sustained-heat source of claim 38, wherein a thermally conductive material is positioned on a side of the thermally conductive encasement for transferring heat to a thermal power generator.

40. The sustained-heat source of claim 39, wherein a thermally insulative material is positioned on other sides of the thermally conductive encasement.

41. The sustained-heat source of claim 38, further comprising a removable hermetic seal covering the openings.

42. The sustained-heat source of claim 38, further comprising an oxidizer delivery manifold in the openings.

43. The sustained-heat source of claim 38, wherein the pyrophoric material is stacked.

44. The sustained-heat source of claim 38 wherein the pyrophoric material is coiled.

45. The sustained-heat source of claim 38, wherein the pyrophoric material includes at least one activated pyrophoric metal.
